(19) United States
(12) Patent Application Publication
(10) Pub. No.: US 2026/0068167 A1
(43) Pub. Date: Mar. 5, 2026

(54) SEMICONDUCTOR MEMORY DEVICE

(71) Applicant: Kioxia Corporation, Tokyo (JP)

(72) Inventor: Kosei Noda, Yokkaichi Mie (JP)

(73) Assignee: Kioxia Corporation, Tokyo (JP)

(21) Appl. No.: 19/001,032

(22) Filed: Dec. 24, 2024

(30) Foreign Application Priority Data
Aug. 29, 2024 (JP) 2024-147639

(51) Int. Cl. H10B 43/35; H01L 23/00; H01L 25/065; H01L 25/18; H10B 43/10; H10B 43/27; H10B 43/40

(52) U.S. Cl. CPC H10B 43/35; H10B 43/10; H10B 43/27; H10B 43/40

(57) ABSTRACT

In general, according to one embodiment, a semiconductor memory device includes: a first interconnect layer provided on a first area; a second interconnect layer arranged apart from the first interconnect layer in a first direction and provided across the first area and a second area in the first direction; a plurality of third interconnect layers provided above the second interconnect layer and spaced apart from each other in the first direction; a third insulating member dividing the second interconnect layer into first and second portions in the third direction; first and second memory pillars extending in the first direction in the first area intersecting the first and the second portion of the second interconnect layer respectively; and first and second contacts extend in the first direction in the first area, electrically coupled to the first and the second portions of the second interconnect layer, respectively.

### CROSS-REFERENCE TO RELATED APPLICATIONS

This application is based upon and claims the benefit of priority from Japanese Patent Application No. 2024-147639, filed Aug. 29, 2024, the entire contents of which are incorporated herein by reference.

### FIELD

Embodiments described herein relate generally to a semiconductor memory device.

### BACKGROUND

A NAND flash memory is known as a semiconductor memory device capable of storing data in a non-volatile manner. In a NAND flash memory, a three-dimensional memory structure may be adopted for high integration and large capacity.

### BRIEF DESCRIPTION OF THE DRAWINGS

FIG. 1 is a block diagram showing an example of a configuration of a memory system according to a first embodiment.

FIG. 2 is a circuit diagram showing an example of a circuit configuration of a memory cell array provided in the semiconductor memory device according to the first embodiment.

FIG. 3 is a perspective view showing an example of an appearance of the semiconductor memory device according to the first embodiment.

FIG. 4 is a perspective view showing an overview of a bonding structure of the semiconductor memory device according to the first embodiment.

FIG. 5 is a plan view showing an example of a planar layout of the memory cell array provided in the semiconductor memory device according to the first embodiment.

FIG. 6 is a plan view showing an example of a planar layout of a memory area of the memory cell array provided in the semiconductor memory device according to the first embodiment.

FIG. 7 is a cross-sectional view taken along line VII-VII in FIG. 6 and shows an example of a cross-sectional structure of the memory area of the memory cell array provided in the semiconductor memory device according to the first embodiment.

FIG. 8 is a cross-sectional view along line VIII-VIII in FIG. 7 and shows an example of the cross-sectional structure of a memory pillar provided in the semiconductor memory device according to the first embodiment.

FIG. 9 is a plan view showing an example of a planar layout of a hookup area of the memory cell array provided in the semiconductor memory device according to the first embodiment.

FIG. 10 is a plan view showing an example of a planar layout of a select gate line SGSa in the hookup area of the memory cell array provided in the semiconductor memory device according to the first embodiment.

FIG. 11 is a cross-sectional view taken along line XI-XI in FIGS. 9 and 10 and shows the hookup area of the memory cell array provided in the semiconductor memory device according to the first embodiment.

FIG. 12 is a cross-sectional view showing an example of a first manufacturing process in which the SGS division structure is manufactured in the memory cell array provided in the semiconductor memory device according to the first embodiment.

FIG. 13 is a cross-sectional view showing an example of the first manufacturing process in which the SGS division structure is manufactured in the memory cell array provided in the semiconductor memory device according to the first embodiment.

FIG. 14 is a cross-sectional view showing an example of a second manufacturing process in which the SGS division structure is manufactured in the memory cell array provided in the semiconductor memory device according to the first embodiment.

FIG. 15 is a cross-sectional view showing an example of the second manufacturing process in which the SGS division structure is manufactured in the memory cell array provided in the semiconductor memory device according to the first embodiment.

FIG. 16 is a plan view showing an example of a planar layout of a select gate line SGSa in a hookup area of the memory cell array provided in a semiconductor memory device according to a first modification of the first embodiment.

FIG. 17 is a plan view showing an example of a planar layout of a hookup area of a memory cell array provided in a semiconductor memory device according to a second embodiment.

FIG. 18 is a plan view showing an example of a planar layout of a hookup area of a memory cell array provided in a semiconductor memory device according to a first modification of the second embodiment.

### DETAILED DESCRIPTION

In general, according to one embodiment, a semiconductor memory device includes: a first interconnect layer provided on a first area; a second interconnect layer arranged apart from the first interconnect layer in a first direction and provided across the first area and a second area that are arranged along a second direction intersecting the first direction; a plurality of third interconnect layers provided on a side of the second interconnect layer that is opposite to the first interconnect layer, and spaced apart from each other in the first direction; a first insulating member and a second insulating member which are arranged in a third direction intersecting the first direction and the second direction, and each of which extends in the second direction and divides the second interconnect layer and the plurality of third interconnect layers in the third direction; a third insulating member provided between the first insulating member and the second insulating member and between the first interconnect layer and the plurality of third interconnect layers, and dividing the second interconnect layer into a first portion and a second portion in the third direction; a first memory pillar extending in the first direction between the first insulating member and the third insulating member in the second area, being in contact with the first interconnect layer, intersecting the first portion of the second interconnect layer, and including portions that intersect the plurality of third interconnect layers and that function as a plurality of first memory cells; a second memory pillar extending in the first direction between the second insulating member and the third insulating member in the second area, being in contact with the first interconnect layer, intersecting the second portion of the second interconnect layer, and including portions that intersect the plurality of third interconnect layers and that function as a plurality of second memory cells; and a first contact and a second contact that extend in the first direction in the first area, wherein the second interconnect layer includes: a first terrace portion that is arranged in the first portion within the first area and that is in contact with the first insulating member and does not overlap the plurality of third interconnect layers as viewed in the first direction; and a second terrace portion that is arranged in the second portion within the first area and that is in contact with the second insulating member and does not overlap the plurality of third interconnect layers as viewed in the first direction, the first contact is electrically coupled to the first terrace portion of the second interconnect layer, and the second contact is electrically coupled to the second terrace portion of the second interconnect layer.

Embodiments will be described below with reference to the accompanying drawings. The drawings are schematic, and the dimensions and scales in the drawings are not necessarily the same as those of the actual products. In the description below, components having the same functions and configurations will be denoted by the same reference symbols. Where elements with similar configurations are specifically distinguished from one another, different letters or numbers may be appended to the same reference symbols.

In the description below, in a case in which a first element is described as being “coupled to” a second element, this includes a case where the first element is coupled indirectly to the second element via an intermediate element that is conductive at all times or at selected times, and a case where the first element is coupled directly to the second element without an intermediate element.

### 1. First Embodiment

### 1.1 Configuration

### 1.1.1 Memory System

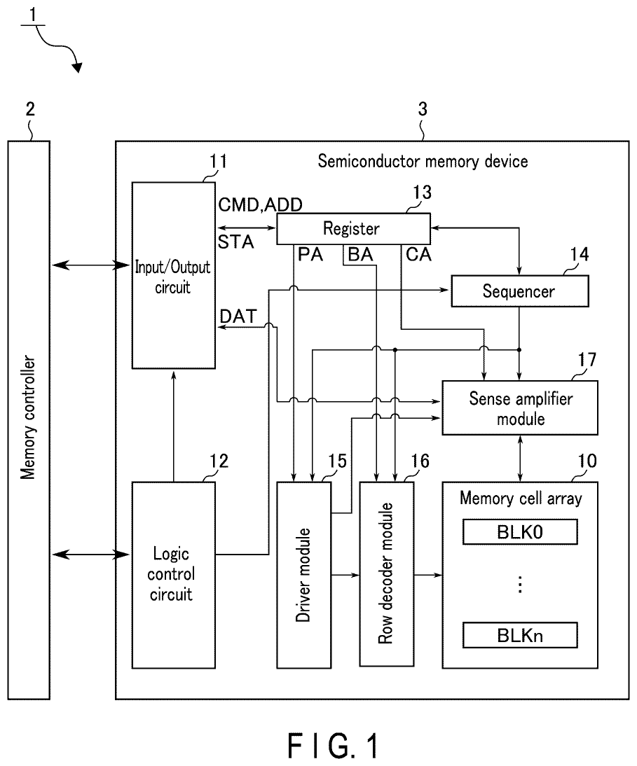

A semiconductor memory device according to a first embodiment will be described. FIG. 1 is a block diagram showing an example of a configuration of a memory system according to the first embodiment. The memory system 1 is a storage device configured to be coupled to an external host device (not shown). The memory system 1 is, for example, a memory card such as an SD™ card, a universal flash storage (UFS), or a solid-state drive (SSD). The memory system 1 includes a memory controller 2 and a semiconductor memory device 3.

The memory controller 2 is configured, for example, as an integrated circuit such as a system on a chip (SoC). The memory controller 2 controls the semiconductor memory device 3, based on a request from the external host device. Specifically, the memory controller 2 writes data requested by the external host device to the semiconductor memory device 3. The memory controller 2 also reads data requested by the external host device from the semiconductor memory device 3 and outputs it to the external host device.

The semiconductor memory device 3 is, for example, a NAND flash memory capable of storing data in a non-volatile manner.

The communication between the memory controller 2 and the semiconductor memory device 3 conforms, for example, to the single data rate (SDR) interface, the toggle double data rate (DDR) interface, or the open NAND flash interface (ONFI).

### 1.1.2 Semiconductor Memory Device

Next, with reference to the block diagram shown in FIG. 1, the internal configuration of the semiconductor memory device 3 according to the first embodiment will be described. The semiconductor memory device 3 includes, for example, a memory cell array 10, an input/output circuit 11, a logic control circuit 12, a register 13, a sequencer 14, a driver module 15, a row decoder module 16, and a sense amplifier module 17.

The memory cell array 10 includes a set of memory cell transistors and a collection of components coupled to the memory cell transistors. The memory cell array 10 includes a plurality of blocks BLK0 to BLKn (n is an integer of 1 or more). A block BLK is a collection of a plurality of memory cell transistors capable of storing data in a non-volatile manner. A block BLK is used, for example, as an erase unit when data stored in the memory cell transistors is erased. The memory cell array 10 includes a plurality of bit lines and a plurality of word lines. Each memory cell transistor is associated, for example, with a combination of one bit line and one word line. A detailed configuration of the memory cell array 10 will be described later.

The input/output circuit 11 is an interface circuit responsible for the transmission/reception of input/output signals to/from the memory controller 2. The input/output signals include, for example, data DAT, a command CMD, address information ADD, and status information STA. The input/output circuit 11 inputs and outputs data DAT between the sense amplifier module 17 and the memory controller 2. The input/output circuit 11 outputs each of the command CMD and address information ADD transferred from the memory controller 2 to the register 13. The input/output circuit 11 outputs the status information STA transferred from the register 13 to the memory controller 2.

The logic control circuit 12 receives a control signal input from the memory controller 2. The logic control circuit 12 controls each of the input/output circuit 11 and the sequencer 14, based on the control signal. For example, the logic control circuit 12 notifies the input/output circuit 11 that the input/output signal received by the input/output circuit 11 is a command CMD, address information ADD, or the like. The logic control circuit 12 instructs the input/output circuit 11 to input or output the input/output signal. The logic control circuit 12 controls the sequencer 14 to enable the semiconductor memory device 3. The logic control circuit 12 also outputs a signal indicating whether the semiconductor memory device 3 is in a ready state or a busy state to the memory controller 2.

The register 13 temporarily stores the command CMD, the address information ADD, and the status information STA. The command CMD includes, for example, instructions for causing the sequencer 14 to execute a read operation, a write operation, an erase operation, or the like. The address information ADD includes, for example, a block address BA, a page address PA, and a column address CA. For example, the block address BA, the page address PA, and the column address CA are used to select a block BLK, a word line, and a bit line, respectively. The status information STA is updated based on the control of the sequencer 14, and is transferred to the input/output circuit 11.

The sequencer 14 controls the overall operation of the semiconductor memory device 3. For example, the sequencer 14 controls the driver module 15, the row decoder module 16, and the sense amplifier module 17, based on the command CMD stored in the register 13, to execute the read operation, the write operation, the erase operation, or the like.

The driver module 15 generates a plurality of voltages of different magnitudes used in the read operation, the write operation, the erase operation, or the like. The driver module 15 supplies the generated voltages to the row decoder module 16 and the sense amplifier module 17, etc. The driver module 15 also applies the generated voltages to a signal line corresponding to a word line that is selected, for example, based on a page address PA stored in the register 13.

The row decoder module 16 selects one of the blocks BLK in the corresponding memory cell array 10, based on the block address BA held in the address register 13. The row decoder module 16 transfers, for example, a signal line voltage applied by the driver module 15 to a selected word line in the selected block BLK.

The sense amplifier module 17 includes a sense amplifier capable of determining data based on the voltage of an associated bit line, a latch circuit for temporarily storing data, etc. In the write operation, the sense amplifier module 17 applies a desired voltage to each bit line in accordance with the write data DAT received from the input/output circuit 11. In the read operation, the sense amplifier module 17 determines the data stored in the memory cell transistor based on the magnitude of the voltage on the bit line. Then, the sense amplifier module 17 transfers a determination result to the input/output circuit 11 as read data DAT.

### 1.1.3 Circuit Configuration of Memory Cell Array

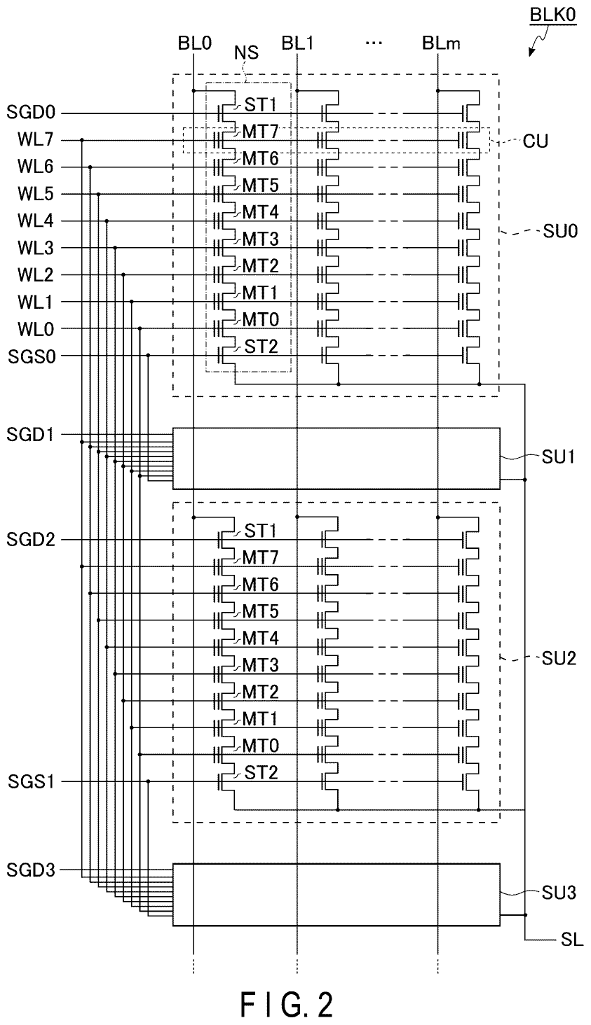

FIG. 2 is a circuit diagram showing an example of a circuit configuration of a memory cell array provided in the semiconductor memory device of the first embodiment. FIG. 2 shows a block BLK0. The Block BLK0 includes, for example, four string units SU0 to SU3.

Each string unit SU includes a plurality of NAND strings NS associated with bit lines BL0 to BLm (m is an integer equal to or greater than 1), respectively. Each NAND string NS includes, for example, eight memory cell transistors MT0 to MT7 and select transistors ST1 and ST2. Each memory cell transistor MT includes a control gate and a charge storage film, and stores data in a non-volatile manner, based on the amount of charge in the charge storage film. Each of the select transistors ST1 and ST2 is used for selecting a string unit SU during various operations.

In each NAND string NS, the memory cell transistors MT0 to MT7 are coupled in series in this order. The drain of the select transistor ST1 is coupled to the associated bit line BL, and the source of the select transistor ST1 is coupled to the drain of the memory cell transistor MT7. The drain of the select transistor ST2 is coupled to the source of the memory cell transistor MT0, and the source of the select transistor ST2 is coupled to a source line SL.

The control gates of the memory cell transistors MT0 to MT7 in the same block BLK are coupled to word lines WL0 to WL7, respectively. The gates of the select transistors ST1 in the string units SU0 to SU3 are coupled to select gate lines SGD0 to SGD3, respectively. The gates of the select transistors ST2 in the string units SU0 to SU1 are coupled to a select gate line SGS0. The gates of the select transistors ST2 in the string units SU2 to SU3 are coupled to a select gate line SGS1.

Different column addresses CA are assigned to the bit lines BL0 to BLm. Each bit line BL is shared among the NAND strings NS that are assigned the same column address CA across the plurality of blocks BLK. Each of the word lines WL0 to WL7 is provided for each block BLK. The source line SL is shared, for example, among the plurality of blocks BLK.

A set of memory cell transistors MT coupled to a common word line WL in one string unit SU are referred to as a cell unit CU. For example, the storage capacity of the cell unit CU including memory cell transistors MT each storing 1-bit data is defined as “1 page data.” The cell unit CU may have a storage capacity of two page data or more in accordance with the number of bits of data stored in each memory cell transistor MT.

The circuit configuration of the memory cell array 10 provided in the semiconductor memory device 3 according to the first embodiment is not limited to the configuration described above. For example, the number of string units SU included in each block BLK may be designed to be an arbitrary number. However, it is desirable that the number of string units SU included in each block BLK be an even number. The number of memory cell transistors MT included in each NAND string NS and the number of select transistors ST1 and ST2 may be designed to be arbitrary numbers.

### 1.1.4 Appearance of Semiconductor Memory Device

The semiconductor memory device 3 according to the first embodiment is formed by bonding two semiconductor circuit boards, each provided with a semiconductor circuit formed thereon, and then separating the bonded semiconductor circuit boards into individual chips. That is, the semiconductor memory device 3 according to the first embodiment includes a structure formed by bonding the semiconductor substrates W1 and W2 to each other. Each of the semiconductor substrates W1 and W2 is, for example, a silicon substrate. In the following, a description will be given of a case in which the semiconductor substrate W2 is removed during the manufacturing process of the semiconductor memory device 3. Depending on the structure of the memory cell array 10, part of the semiconductor substrate W2 may remain after bonding.

FIG. 3 is a perspective view showing an example of an appearance of the semiconductor memory device according to the first embodiment. Hatching is added to FIG. 3 to improve the visibility within the drawing, but the added hatching is not necessarily related to the materials or characteristics of the hatched components. As shown in FIG. 3, the semiconductor memory device 3 has a structure in which, for example, a semiconductor substrate W1, a control circuit layer 100, a bonding layer B1, a bonding layer B2, a memory layer 200, and an interconnect layer 300 are stacked in this order.

In the description below, the plane in which the semiconductor substrate W1 extends will be referred to as an XY plane. Among the directions in which the stacked structure is provided, the direction from the semiconductor substrate W1 toward the interconnect layer 300 will be referred to as a Z1 direction, and the direction from the interconnect layer 300 toward the semiconductor substrate W1 will be referred to as a Z2 direction. The Z1 direction and the Z2 direction are approximately perpendicular to the semiconductor substrate W1. In a case where the Z1 direction and the Z2 direction need not be distinguished, each of the Z1 direction and the Z2 direction will be referred to simply as a Z direction.

The control circuit layer 100 includes a control circuit formed using the semiconductor substrate W1. The semiconductor substrate W1 includes an impurity diffusion area and the like in accordance with the design of the control circuit. The control circuit layer 100 includes, for example, the input/output circuit 11, the logic control circuit 12, the register 13, the sequencer 14, the driver module 15, the row decoder module 16, and the sense amplifier module 17.

The bonding layer B1 is formed using the semiconductor substrate W1. The bonding layer B1 includes a plurality of bonding pads that are electrically coupled to the control circuit provided in the control circuit layer 100 and that form part of the semiconductor circuit.

The bonding layer B2 is formed using a semiconductor substrate W2 (not shown). The bonding layer B2 includes a plurality of bonding pads that are electrically coupled to the memory cell array 10 provided in the memory layer 200 and that form part of the semiconductor circuit.

The memory layer 200 includes the memory cell array 10 formed using the semiconductor substrate W2 (not shown).

The interconnect layer 300 is formed after the semiconductor substrates W1 and W2 are bonded to each other. The interconnect layer 300 includes interconnects coupled to the semiconductor circuit provided in the memory layer 200 and a plurality of pads PD. The plurality of pads PD are exposed on the surface of the semiconductor memory device 3. The plurality of pads PD are used for coupling the semiconductor memory device 3 to the memory controller 2, etc.

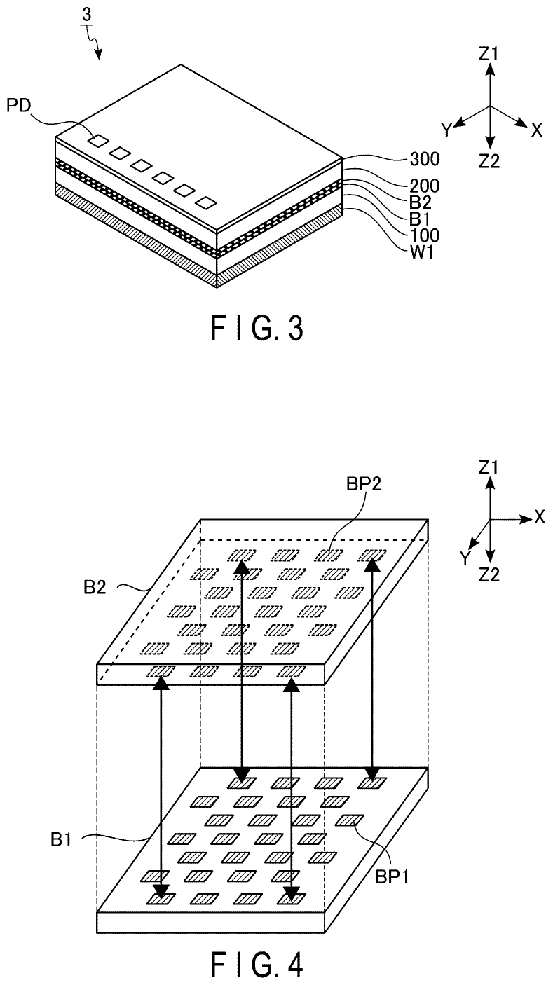

FIG. 4 is a perspective view showing an overview of a bonding structure of the semiconductor memory device according to the first embodiment. The bonding of the semiconductor substrates W1 and W2 will be described with reference to FIG. 4.

As shown in FIG. 4, a plurality of bonding pads BP1 included in the bonding layer B1 and a plurality of bonding pads BP2 included in the bonding layer B2 are coupled to each other. Thus, the control circuits provided in the control circuit layer 100 and the memory cell arrays 10 provided in the memory layer 200 are electrically coupled to each other via the bonding pads BP1 and BP2. The region between the bonding layers B1 and B2 corresponds to the boundary between the layer formed using the semiconductor substrate W1 and the layer formed using the semiconductor substrate W2 (not shown).

### 1.1.5 Structure of Memory Cell Array

In the following, a description will be given of an example of the structure of the memory cell array 10 provided in the semiconductor memory device 3 according to the first embodiment. In the description below, the X direction corresponds to the direction in which the word lines WL extend. The Y direction corresponds to the direction in which the bit lines BL extend. The plane extending in the X and Z directions is an XZ plane. The plane extending in the Y and Z directions is a YZ plane. In the plan views, hatching is added as appropriate to improve the visibility within the drawings. The hatching added to the plan view is not necessarily related to the materials or characteristics of the hatched component. In the cross-sectional views, illustration of the configuration is omitted as appropriate to improve the visibility within the drawings.

### 1.1.5.1 Overview

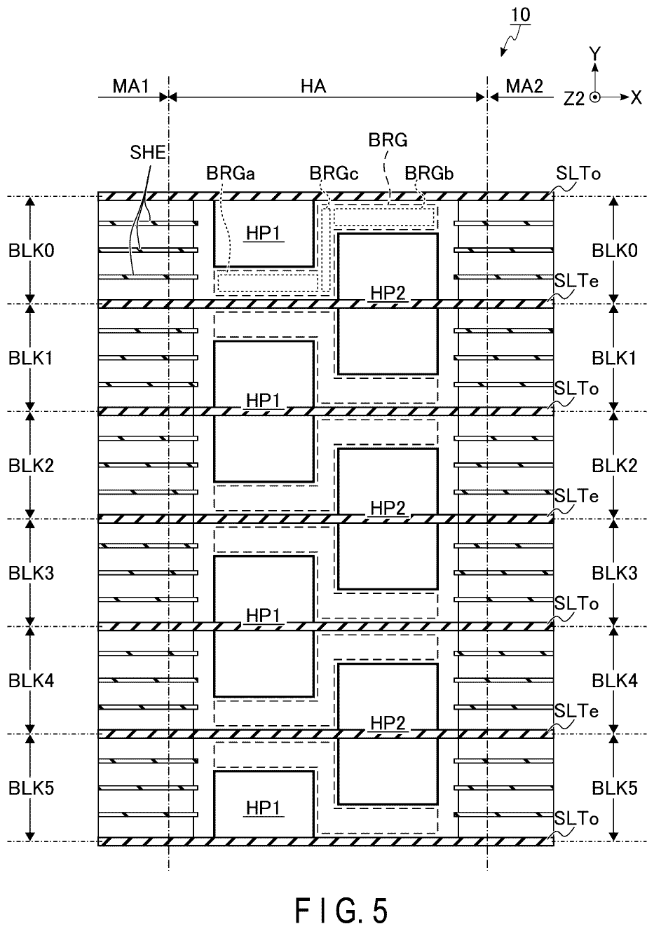

FIG. 5 is a plan view showing an example of a planar layout of the memory cell array provided in the semiconductor memory device according to the first embodiment. In FIG. 5, areas corresponding to six blocks BLK0 to BLK5 are shown. The serial numbers at the end for distinguishing the blocks BLK are assigned in ascending order from the top of the drawing sheet. In the memory cell array 10, for example, the layout shown in FIG. 5 is repeatedly arranged in the Y direction. As shown in FIG. 5, the memory cell array 10 includes a plurality of members SLT and a plurality of members SHE. The planar layout of the memory cell array 10 is divided, for example, in the X direction into memory areas MA1 and MA2 and a hookup area HA. The hookup area HA is provided between the memory areas MA1 and MA2.

The memory areas MA1 and MA2 are areas used for storing data and each includes a plurality of NAND strings NS. The hookup area HA is an area where stacked interconnects, which are formed by stacking a plurality of interconnect layers (e.g., word lines WL0 to WL7 and select gate lines SGS0, SGS1, and SGD) at intervals in the Z direction, are coupled to the row decoder module 16.

The plurality of members SLT each extend along the X direction and are aligned in the Y direction. Each member SLT crosses the memory areas MA1 and MA2 in the X direction in the boundary area between adjacent blocks BLK. In other words, each of the areas partitioned by the members SLT corresponds to one block BLK in the memory cell array 10. Each member SLT has a structure in which, for example, an insulator and a plate-shaped contact are embedded inside. Each member SLT separates the stacked interconnects adjacent to each other via the member SLT.

As shown in FIG. 5, in the present embodiment, among the plurality of members SLT aligned in the Y direction, the odd-numbered members SLT counted from the top of the drawing sheet are referred to as “SLTo” and the even-numbered members SLT are referred to as “SLTe.” In the memory cell array 10, a plurality of pairs each consisting of one member SLTo and one member SLTe are aligned in the Y direction.

The plurality of members SHE are arranged in each of the memory areas MA1 and MA2. The plurality of members SHE corresponding to the memory area MA1 each cross the memory area MA1 in the X direction and are aligned in the Y direction. The plurality of members SHE corresponding to the memory area MA2 each cross the memory area MA2 in the X direction and are aligned in the Y direction. The ends of the members SHE corresponding to the memory area MA1 and shown on the right in the drawing sheet and the ends of the members SHE corresponding to the memory area MA2 and shown on the left in the drawing sheet are positioned in the hookup area HA. For example, in each of the memory areas MA1 and MA2, three members SHE are arranged between the members SLT adjacent in the Y direction. A combination of each of the areas partitioned by the members SLT and SHE in the memory area MA1 and each of the areas partitioned by the members SLT and SHE in the memory area MA2 corresponds to one string unit SU in the memory cell array 10. Each member SHE has, for example, a structure in which an insulator is embedded. Each member SHE divides select gate lines SGD that are adjacent via the member SHE.

It should be noted that the planar layout of the memory cell array 10 provided in the semiconductor memory device 3 according to the first embodiment is not limited to that described above. For example, the number of members SHE arranged between the adjacent members SLT can be designed to be an arbitrary number. The number of string units SU formed between the adjacent members SLT can be changed, based on the number of members SHE arranged between the adjacent members SLT. It is preferable that the number of string units SU formed between the adjacent members SLT be an even number. In other words, it is preferable that the number of members SHE in one block BLK be an odd number.

The hookup area HA includes a plurality of hookup portions HP1 and HP2. In each of the hookup portions HP1 and HP2, a coupling portion is provided to couple to a contact in each interconnect layer of the stacked interconnects. The hookup portions HP1 are aligned in the Y direction and are provided for two blocks BLK that are adjacent in the Y direction with the members SLTo in between. In other words, each hookup portion HP1 is provided in the hookup area HA such that it is sandwiched between two members SLTe that sandwich two adjacent blocks BLK. The hookup portions HP2 are aligned in the Y direction and are each provided for two blocks BLK adjacent in the Y direction with the members SLTe in between. In other words, each hookup portion HP2 is provided in the hookup area HA such that it is sandwiched between two members SLTo that sandwich two adjacent blocks BLK.

The hookup area HA includes a plurality of bridge portions BRG. Each bridge portion BRG is provided for each block BLK. In each bridge portion BRG, a portion of each interconnect layer of the stacked interconnects provided in the memory area MA1 and a corresponding portion provided in the memory area MA2 are coupled to each other. Each bridge portion BRG includes a first portion BRGa that is provided between the hookup portion HP1 and the member SLTe so as to be sandwiched between them in the Y direction, a second portion BRGb that is provided between the hookup portion HP2 and the member SLTo so as to be sandwiched between them in the Y direction, and a third portion BRGc that is provided between the hookup portion HP1 and the hookup portion HP2 so as to be sandwiched between them in the X direction and that couples the first portion BRGa and the second portion BRGb to each other. Each bridge portion BRG has, for example, an S-shape.

### 1.1.5.2 Memory Area

### (Planar Layout)

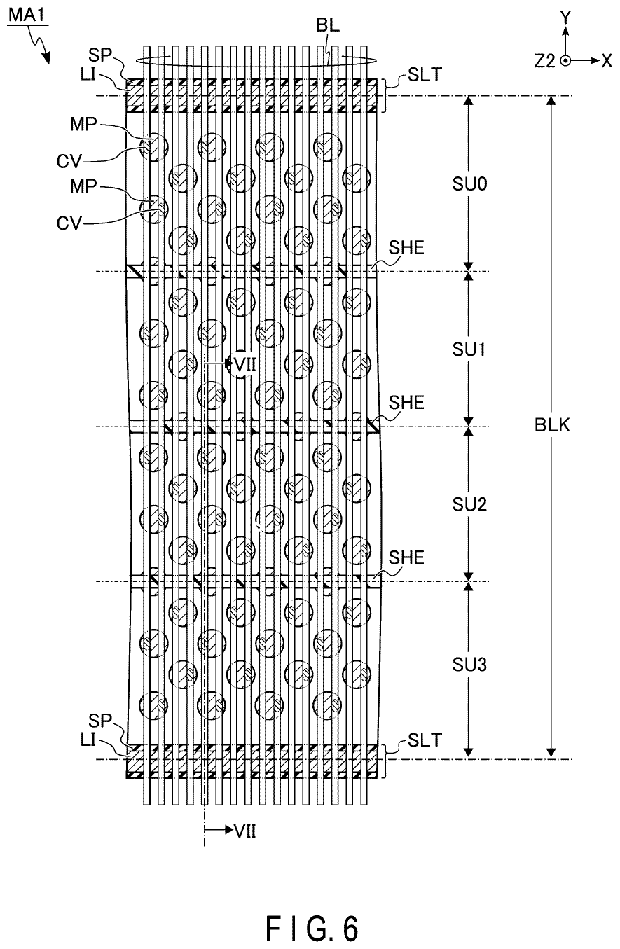

FIG. 6 is a plan view showing an example of a planar layout of a memory area of the memory cell array provided in the semiconductor memory device according to the first embodiment. It should be noted that FIG. 6 shows the structure of one block BLK in the memory area MA1 as a representative, but the structure of the memory area MA2 is similar to that of the memory area MA1. As shown in FIG. 6, in the memory areas MA1 and MA2, the memory cell array 10 includes a plurality of memory pillars MP, a plurality of contacts CV, and a plurality of bit lines BL. Each member SLT includes a contact LI and a spacer SP.

Each of the memory pillars MP functions, for example, as one NAND string NS. In the area between two adjacent members SLT, the plurality of memory pillars MP are arranged, for example, in 19 rows in the Y direction and in a staggered fashion. In the example shown in FIG. 6, one member SHE overlaps the memory pillars MP in the 5th, 10th, and 15th rows, counting from the top of the drawing sheet.

The plurality of bit lines BL extend in the Y direction and are arranged in the X direction. Each bit line BL is arranged such that it overlaps at least one memory pillar MP in each string unit SU. In the example shown in FIG. 6, two bit lines BL are arranged so as to overlap one memory pillar MP. In a case where the plurality of bit lines BL overlap the memory pillar MP, one of the plurality of bit lines BL is electrically coupled to the corresponding memory pillar MP via a contact CV. In a case where only one bit line BL overlaps the memory pillar MP, the bit line BL is electrically coupled to the corresponding memory pillar MP via the contact CV.

For example, the contact CV between the memory pillar MP in contact with the member SHE and the corresponding bit line BL is omitted. In other words, the contact CV between the memory pillar MP in contact with two different select gate lines SGD and the bit line BL is omitted. The numbers and arrangements of memory pillars MP and members SHE provided between adjacent members SLT are not limited to those shown in FIG. 6 and can be changed as appropriate. For example, the number of bit lines BL overlapping each memory pillar MP can be designed to be an arbitrary number.

The contact LI is a conductor spreading in the XZ plane. The lower face of the contact LI is in contact with a source line SL (not shown). The spacer SP is an insulator provided on the side face of the contact LI. In other words, the spacer SP is provided in contact with the contact LI so as to sandwich the contact LI in the Y direction.

### (Cross-Sectional Structure)

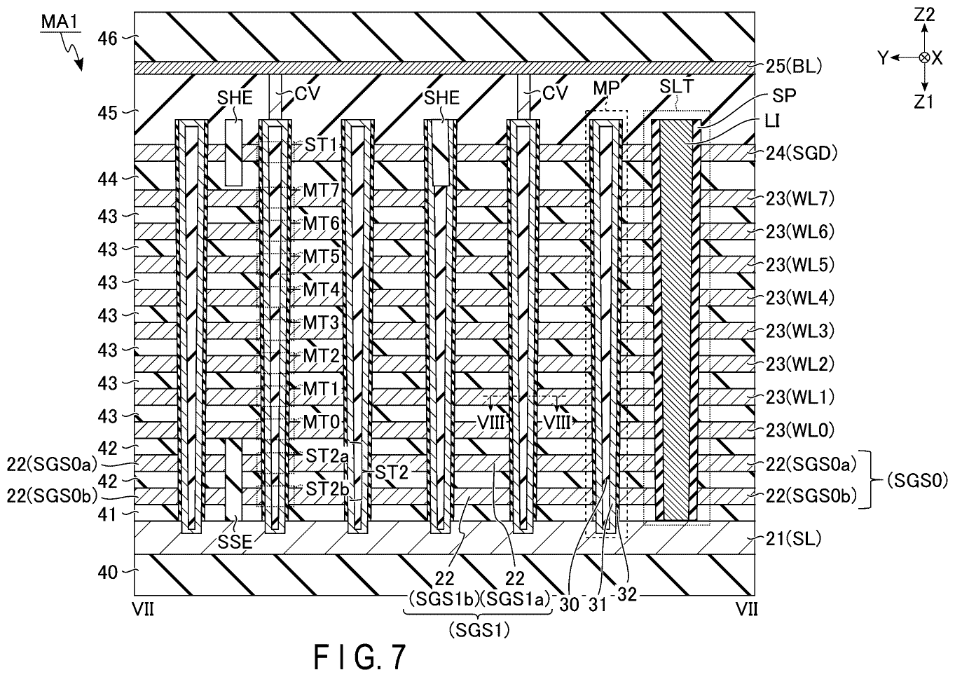

FIG. 7 is a cross-sectional view taken along line VII-VII in FIG. 6 and shows an example of the cross-sectional structure in the memory area of the memory cell array provided in the semiconductor memory device according to the first embodiment. As shown in FIG. 7, the memory cell array 10 further includes interconnect layers 21-25, insulating layers 40-46, and a member SSE. In the description below, it is assumed that the Z2 direction is the upward direction and the Z1 direction is the downward direction.

The stacked interconnects included in the memory cell array 10 include interconnect layers 22 corresponding to the select gate lines SGS0 and SGS1, a plurality of interconnect layers 23 corresponding to the word lines WL0-WL7, respectively, and an interconnect layer 24 corresponding to the select gate line SGD. In a case where the select gate lines SGS0 and SGS1 do not have to be distinguished, they will be simply referred to as select gate lines SGS.

In the example shown in FIG. 7, two interconnect layers 22 are provided to correspond to the select gate line SGS. In the description below, the select gate line SGS corresponding to the upper interconnect layer 22 will be referred to as a select gate line SGSa, and the select gate line SGS corresponding to the lower interconnect layer 22 will be referred to as a select gate line SGSb. The select gate lines SGSa and SGSb are coupled to the gates of select transistors ST2a and ST2b, respectively. The select transistors ST2a and ST2b function as one select transistor ST2. The interconnect layer 22 corresponding to the select gate line SGS may be one layer or may be three or more layers. In a case where the interconnect layer 22 corresponding to the select gate line SGS is formed in a plurality of layers, each of the select transistors ST2a and ST2b may be configured to function independently.

An insulating layer 41 is stacked above a semiconductor substrate W2 (not shown), and a plurality of interconnect layers 22 and a plurality of insulating layers 42 are alternately stacked above the insulating layer 41. In the example shown in FIG. 7, two interconnect layers 22 and two insulating layers 42 are alternately stacked. Each of the plurality of interconnect layers 22 is formed, for example, in a plate shape extending along the X direction in the XY plane. The interconnect layers 22 are used as select gate lines SGSa and SGSb. The interconnect layers 22 contain, for example, tungsten (W). The insulating layer 41 and the plurality of insulating layers 42 each contain silicon oxide (SiO), for example.

Above the uppermost insulating layer 42, a plurality of interconnect layers 23 and a plurality of insulating layers 43 are alternately stacked. In the example shown in FIG. 7, eight interconnect layers 23 and seven insulating layers 43 are alternately stacked. Each of the interconnect layers 23 is formed, for example, in a plate shape extending along the X direction in the XY plane. The interconnect layers 23 are used as word lines WL0 to WL7, respectively, in order from the side of the interconnect layer 22. The interconnect layers 23 contain, for example, tungsten. Each of the insulating layers 43 contains, for example, silicon oxide.

An insulating layer 44, an interconnect layer 24 and an insulating layer 45 are stacked in this order above the uppermost interconnect layer 23. The interconnect layer 24 is formed, for example, in a plate shape extending along the X direction in the XY plane. The interconnect layer 24 is used as a select gate line SGD. The interconnect layer 24 contains, for example, tungsten. The insulating layers 44 and 45 contain, for example, silicon oxide.

An interconnect layer 25 is stacked above the insulating layer 45. The interconnect layer 25 is formed, for example, in a line shape extending along the Y direction. The interconnect layer 25 is used as a bit line BL. In an area not shown, the plurality of interconnect layers 25 are aligned along the X direction. The interconnect layer 25 contains, for example, copper.

An insulating layer 46 is stacked above the interconnect layer 25. The insulating layer 46 is a layer coupled to a bonding layer B2 and includes a plurality of interconnects (not shown).

After the semiconductor substrate W2 is removed, an interconnect layer 21 and an insulating layer 40 are provided in this order in the Z1 direction below the insulating layer 41. The interconnect layer 21 is formed, for example, in a plate shape extending along the X direction in the XY plane. The interconnect layer 21 is used as a source line SL. The interconnect layer 21 contains, for example, silicon doped with phosphorus. Furthermore, an interconnect layer 300 may be provided below the insulating layer 40. The interconnect layer 300 includes a plurality of interconnects (not shown).

Each of the memory pillars MP is provided extending along the Z direction. The memory pillars MP penetrate the interconnect layers 22 to 24 and the insulating layers 41 to 44. For example, each memory pillar MP has a cross-sectional area (XY cross-sectional area) that increases from the bottom to the top along the XY plane.

Each of the memory pillars MP includes, for example, a core film 30, a semiconductor film 31, and a stacked film 32. The core film 30 is provided to extend along the Z direction. For example, the upper end of the core film 30 is located in the insulating layer 45, and the lower end of the core film 30 is located in the interconnect layer 21. The core film 30 includes an insulator such as silicon oxide. The semiconductor film 31 covers, for example, the periphery of the core film 30. At the lower end of the memory pillar MP, part of the semiconductor film 31 is in contact with the interconnect layer 21. The semiconductor film 31 contains, for example, silicon. The stacked film 32 covers the side face of the semiconductor film 31 except for the portion where the semiconductor film 31 and the interconnect layer 21 are in contact with each other.

In the structure of the memory pillar MP shown in FIG. 7, the portions where the memory pillar MP intersects the interconnect layers 22 function as select transistors ST2. The portions where the memory pillar MP intersects the interconnect layers 23 function as the memory cell transistors MT0 to MT7, respectively. The portion where the memory pillar MP intersects the interconnect layer 24 functions as a select transistor ST1.

A columnar contact CV is provided on the upper face of the semiconductor film 31 in the memory pillar MP. In the area shown in FIG. 7, two contacts CV are shown corresponding to two of the six memory pillars MP. In areas not shown, another contact CV is coupled to each memory pillar MP that does not overlap the member SHE and is not coupled to the contact CV in the area shown in FIG. 7.

One interconnect layer 25, i.e., one bit line BL, is in contact with the upper face of each contact CV. One contact CV is coupled to the interconnect layer 25 in the spaces partitioned by the members SLT and SHE. In other words, each interconnect layer 25 is electrically coupled, for example, to one memory pillar MP in each area between the adjacent members SLT and SHE and to one memory pillar MP in each area between two adjacent members SHE.

The member SLT is formed to spread along the XZ plane, for example. Each of the members SLT penetrates the interconnect layers 22 to 24 and the insulating layers 41 to 44. For example, each of the members SLT increases in width in the Y direction from the bottom to the top.

Within each member SLT, the contact LI is arranged to spread along the XZ plane, and the spacer SP is provided between the contact LI and the interconnect layers 22 to 24 and the insulating layers 41 to 45. The upper end of the contact LI is located, for example, in the insulating layer 45. The lower end of the contact LI is in contact, for example, with the interconnect layer 21. It should be noted that the contact LI may be omitted depending on the structure of the memory cell array 10.

The member SHE is formed, for example, in a plate shape spreading along the XZ plane, and divides the interconnect layer 24. The upper end of the member SHE is located in the insulating layer 45. The lower end of the member SHE is located, for example, in the uppermost insulating layer 43. The member SHE includes, for example, an insulator such as silicon oxide. The upper end of the member SHE and the upper end of the member SLT may or may not be aligned. The upper end of the member SHE and the upper end of the memory pillar MP may or may not be aligned.

A member SSE is formed in the memory areas MA1 and MA2, for example, in a plate shape spreading along the XZ plane, and divides the plurality of interconnect layers 22. For example, the upper end of the member SSE may be located at the boundary between the uppermost insulating layer 42 and the lowermost interconnect layer 23 or may be located inside the uppermost insulating layer 42. For example, the lower end of the member SSE may be located at the boundary between the interconnect layer 21 and the insulating layer 41 or may be located inside the insulating layer 41. Preferably, the member SSE is provided at a position overlapping one member SHE in the Z direction in the memory areas MA1 and MA2. The member SSE includes, for example, an insulator such as silicon oxide. The lower end of the member SSE and the lower end of the member SLT may or may not be aligned.

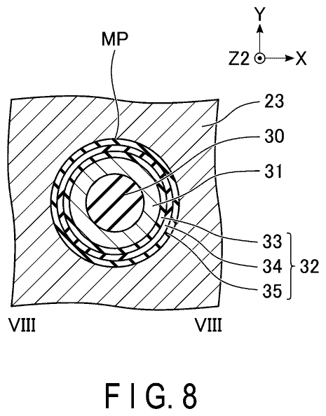

FIG. 8 is a cross-sectional view taken along line VIII-VIII in FIG. 7 and shows an example of the cross-sectional structure of a memory pillar provided in the semiconductor memory device according to the first embodiment. More specifically, FIG. 8 shows a cross-sectional structure of a memory pillar MP in a layer that is parallel to the surface of the semiconductor substrate W2 (not shown) and that includes the interconnect layer 23. As shown in FIG. 8, the stacked film 32 includes, for example, a tunnel insulating film 33, a charge storage film 34, and a block insulating film 35.

In the cross section including the interconnect layer 23, the core film 30 is provided, for example, in the center of the memory pillar MP. The semiconductor film 31 surrounds the side face of the core film 30. The tunnel insulating film 33 surrounds the side face of the semiconductor film 31. The charge storage film 34 surrounds the side face of the tunnel insulating film 33. The block insulating film 35 surrounds the side face of the charge storage film 34. The interconnect layer 23 surrounds the side face of the block insulating film 35.

The semiconductor film 31 is used as a channel (current path) of the memory cell transistors MT0 to MT7 and the select transistors ST1 and ST2. Each of the tunnel insulating film 33 and the block insulating film 35 contains silicon oxide, for example. The charge storage film 34 has the function of storing charge and contains silicon nitride (SiN), for example. With this configuration, each memory pillar MP can function as a single NAND string NS.

### 1.1.5.3 Hookup Area

### (Planar Layout)

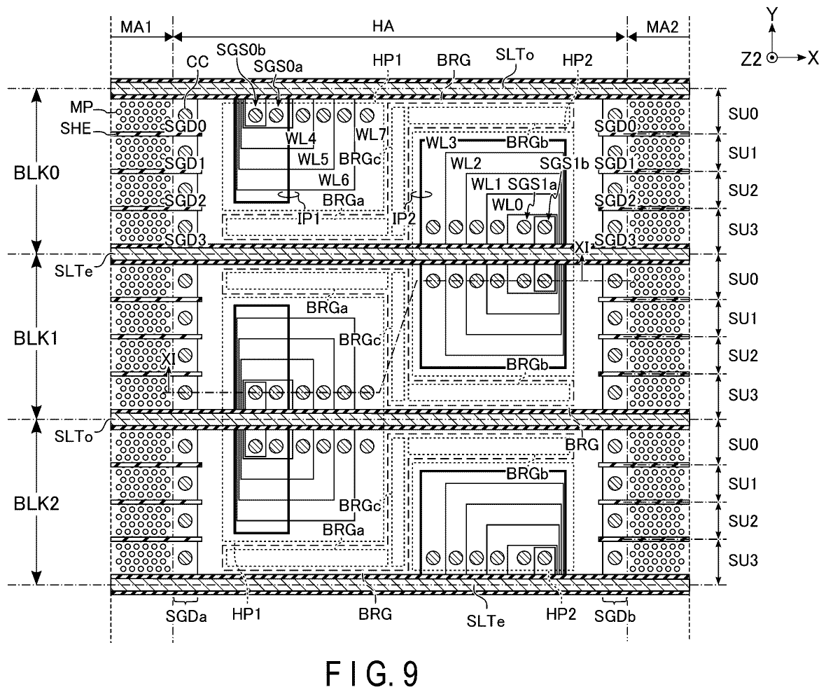

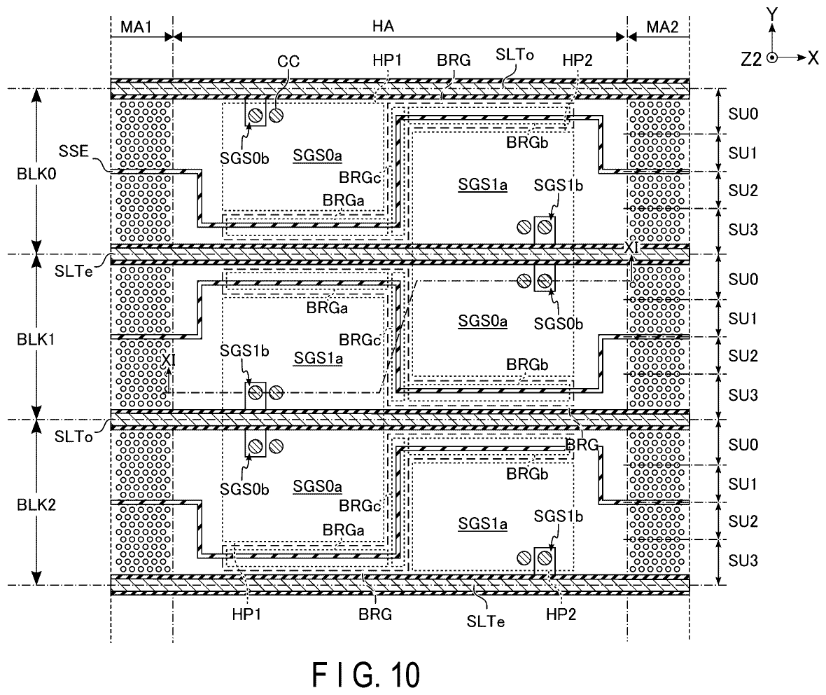

FIG. 9 is a plan view showing an example of a planar layout of the hookup area of the memory cell array provided in the semiconductor memory device according to the first embodiment. FIG. 10 is a plan view showing an example of a planar layout of the select gate line SGSa in the hookup area of the memory cell array provided in the semiconductor memory device according to the first embodiment. FIGS. 9 and 10 show the hookup area HA and portions of the neighboring memory areas MA1 and MA2. The areas shown in FIGS. 9 and 10 correspond to the blocks BLK0 to BLK2. It should be noted that some insulating layers are omitted in FIGS. 9 and 10 for the sake of simplicity.

As shown in FIGS. 9 and 10, in the hookup area HA, the memory cell array 10 further includes a plurality of contacts CC.

As shown in FIG. 9, the select gate line SGD includes a first portion SGDa coupled to the memory area MA1 and a second portion SGDb coupled to the memory area MA2. Moreover, the select gate line SGD is divided into four portions in the Y direction by three members SHE, and thus includes select gate lines SGD0 to SGD3 in each of the first portion SGDa and the second portion SGDb. The select gate lines SGD0 to SGD3 divided in the Y direction by the three members SHE are insulated from each other. That is, in one block BLK, the select gate line SGD is divided into eight portions. It should be noted that corresponding portions of the first portion SGDa and the second portion SGDb are electrically coupled to each other via contacts CC (described later) and an upper interconnect layer (not shown).

As shown in FIG. 10, each of the members SSE divides the select gate line SGS in the Y direction in the hookup area HA. Although not shown, each of the members SSE also divides the select gate line SGS in the Y direction in the memory areas MA1 and MA2. The member SSE is formed in a plate shape spreading along the XZ plane in the portion extending in the X direction, and in a plate shape spreading along the YZ plane in the portion extending in the Y direction. The select gate line SGSa includes select gate lines SGS0a and SGS1a divided in the Y direction by the member SSE. The select gate lines SGS0a and SGS1a are insulated from each other. For example, in the memory areas MA1 and MA2, the select gate line SGS0a is coupled to the memory pillars MP corresponding to the string units SU0 and SU1. In the select gate line SGS0a, the portion provided in the memory area MA1 and the portion provided in the memory area MA2 are electrically coupled to each other via a portion provided in the bridge portion BRG in the hookup area HA. In the memory areas MA1 and MA2, the select gate line SGS1a is coupled to the memory pillars MP corresponding to the string units SU2 and SU3. In the select gate line SGS1a, the portion provided in the memory area MA1 and the portion provided in the memory area MA2 are electrically coupled to each other via a portion provided in the bridge portion BRG in the hookup area HA. For example, the select gate lines SGS0a and SGS1a have shapes that overlap each other when rotated about the Z-axis. The cross-sectional area of the select gate line SGS0a in the XY plane and the cross-sectional area of the select gate line SGS1a in the XY plane are approximately equal to each other. Therefore, the electric capacitance of the select gate line SGS0a and the electric capacitance of the select gate line SGS1a are approximately equal to each other.

Although not shown, the select gate line SGSb also includes select gate lines SGS0b and SGS1b divided in the Y direction by the member SSE. The select gate lines SGS0b and SGS1b are insulated from each other. For example, in the memory areas MA1 and MA2, the select gate line SGS0b is coupled to the memory pillars MP corresponding to the string units SU0 and SU1. In the select gate line SGS0b, the portion provided in the memory area MA1 and the portion provided in the memory area MA2 are electrically coupled to each other via a portion provided in the bridge portion BRG in the hookup area HA. In the memory areas MA1 and MA2, the select gate line SGS1b is coupled to the memory pillars MP corresponding to the string units SU2 and SU3. In the select gate line SGS1b, the portion provided in the memory area MA1 and the portion provided in the memory area MA2 are electrically coupled to each other via a portion provided in the bridge portion BRG in the hookup area HA. For example, the select gate lines SGS0b and SGS1b have shapes that overlap each other when rotated about the Z-axis. The cross-sectional area of the select gate line SGS0b in the XY plane and the cross-sectional area of the select gate line SGS1b in the XY plane are approximately equal to each other. Therefore, the electric capacitance of the select gate line SGS0b and the electric capacitance of the select gate line SGS1b are approximately equal to each other.

As described above, a structure in which the select gate line SGS is divided into a plurality of portions by the member SSE within one block BLK is referred to as an SGS division structure.

The member SSE is provided in the bridge portion BRG such that it bypasses the hookup portions HP1 and HP2 and does not overlap the member SLT in the Z direction in the hookup area HA. Specifically, the member SSE extends, for example, in the X direction in the first portion BRGa and the second portion BRGb of the bridge portion BRG, and extends in the Y direction in the third portion BRGc of the bridge portion BRG. The member SSE has, for example, an S-shape in the hookup area HA. For example, the shape of the member SSE in one block BLK is symmetric in the Y direction to the shape of the member SSE in the adjacent block (BLK) via the member SLT, with respect to the member SLT as the axis of symmetry.

As shown in FIG. 9, in the hookup area HA, each of the interconnect layers 22-23 includes a terrace portion that does not overlap the upper interconnect layers 23 and 24. The shape of the terrace portion in the hookup area HA is similar to features such as a step, a terrace, a rimstone, etc. Contacts CC are coupled to the terrace portions of the interconnect layers 22-23.

Specifically, as shown in FIG. 9, a first staircase structure is provided in which the terrace portions of the interconnect layers 22 corresponding to the select gate lines SGS0a and SGS0b and the terrace portions of the interconnect layers 23 corresponding to the word lines WL4-WL7 are aligned in the X direction in the hookup portion HP1. The first staircase structure is provided so as to span the member SLTo and has a symmetrical structure with respect to the member SLTo. In the hookup portion HP2, a second staircase structure is provided in which the terrace portions of the interconnect layers 22 corresponding to the select gate lines SGS1a and SGS1b and the terrace portions of the interconnect layers 23 corresponding to the word lines WL0 to WL3 are aligned in the X direction. The second staircase structure is provided to span the member SLTe and has a structure symmetrical with respect to the member SLTe.

The plurality of interconnect layers 23 include an inclined portion IP1 in the hookup portion HP1. The inclined portion IP1 is defined as steps including the ends of the plurality of interconnect layers 23 (four interconnect layers in the example shown in FIG. 9), which are continuously stacked and arranged in a rectangular shape in a plan view. Part of the inclined portion IP1 is provided so as to cross the first staircase structure in the Y direction. In the inclined portion IP1, the ends of the plurality of interconnect layers 23, which are stacked continuously, are inclined at approximately the same angle in both the XZ plane and YZ plane, forming an inclined surface. The inclined portion IP1 is provided so as to surround the terrace portion of the interconnect layer 22 corresponding to the select gate lines SGS0a and SGS0b. The plurality of interconnect layers 23 include an inclined portion IP2 in the hookup portion HP2. The inclined portion IP2 is defined as steps including the ends of the plurality of interconnect layers 23 (four interconnect layers in the example shown in FIG. 9), which are continuously stacked and are provided in a rectangular shape in a plan view. The inclined portion IP2 is provided so as to surround the second staircase structure. In the inclined portion IP2, the ends of the plurality of interconnect layers 23, which are continuously stacked, are inclined at approximately the same angle in both the XZ and YZ planes, forming an inclined surface.

Each of the plurality of interconnect layers 23 electrically couples the portion provided in the memory area MA1 and the portion provided in the memory area MA2 to each other via the portion provided in the bridge portion BRG in the hookup area HA. In other words, the same interconnect layer 23 has the same potential regardless of the portion.

A plurality of contacts CC are provided corresponding to the select gate lines SGS0a, SGS1a, SGS0b, SGS1b and SGD0 to SGD3, and the word lines WL0 to WL7, respectively. As shown in FIG. 9, the contacts CC corresponding to the select gate lines SGD0 to SGD3 are aligned in the Y direction and are provided in the first portion SGDa and the second portion SGDb such that one is provided for each area divided by a plurality of members SHE. That is, in one block BLK, eight contacts CC are provided for the select gate lines SGD. The contacts CC corresponding to the word lines WL4 to WL7 are aligned in the X direction in the hookup portion HP1. The contacts CC corresponding to the word lines WL0 to WL3 are aligned in the X direction in the hookup portion HP2.

The contacts CC corresponding to the select gate lines SGS0a, SGS1a, SGS0b, and SGS1b are arranged in different positions depending on whether the block BLK in which the contacts CC are provided is an even-numbered or an odd-numbered block counting from the top of the drawing sheet. In the even-numbered blocks BLK (BLK0, BLK2, . . . ), the contacts CC corresponding to the select gate lines SGS0a and SGS0b are provided in the hookup portion HP1, and the contacts CC corresponding to the select gate lines SGS1a and SGS1b are provided in the hookup portion HP2. In the example shown in FIG. 9, in the even-numbered blocks BLK0 and BLK2, for example, the contacts CC provided in the hookup portion HP1 correspond to the select gate lines SGS0b and SGS0a and the word lines WL4, WL5, WL6 and WL7, respectively, in order from the left side of the drawing sheet. The contacts CC provided in the hookup portion HP2 correspond to the word lines WL3, WL2, WL1 and WL0 and the select gate lines SGS1a and SGS1b, respectively, in order from the left side of the drawing sheet. On the other hand, in the odd-numbered blocks BLK (BLK1, BLK3, . . . ), the contacts CC corresponding to the select gate lines SGS0a and SGS0b are provided in the hookup portion HP2, and the contacts CC corresponding to the select gate lines SGS1a and SGS1b are provided in the hookup portion HP1. In the example shown in FIG. 9, in the odd-numbered block BLK1, for example, the contacts CC provided in the hookup portion HP1 correspond to the select gate lines SGS1b and SGS1a and the word lines WL4, WL5, WL6 and WL7, respectively, in order from the left side of the drawing sheet. The contacts CC provided in the hookup portion HP2 correspond to the word lines WL3, WL2, WL1 and WL0 and the select gate lines SGS0a and SGS0b, respectively, in order from the left side of the drawing sheet.

### (Cross-Sectional Structure)

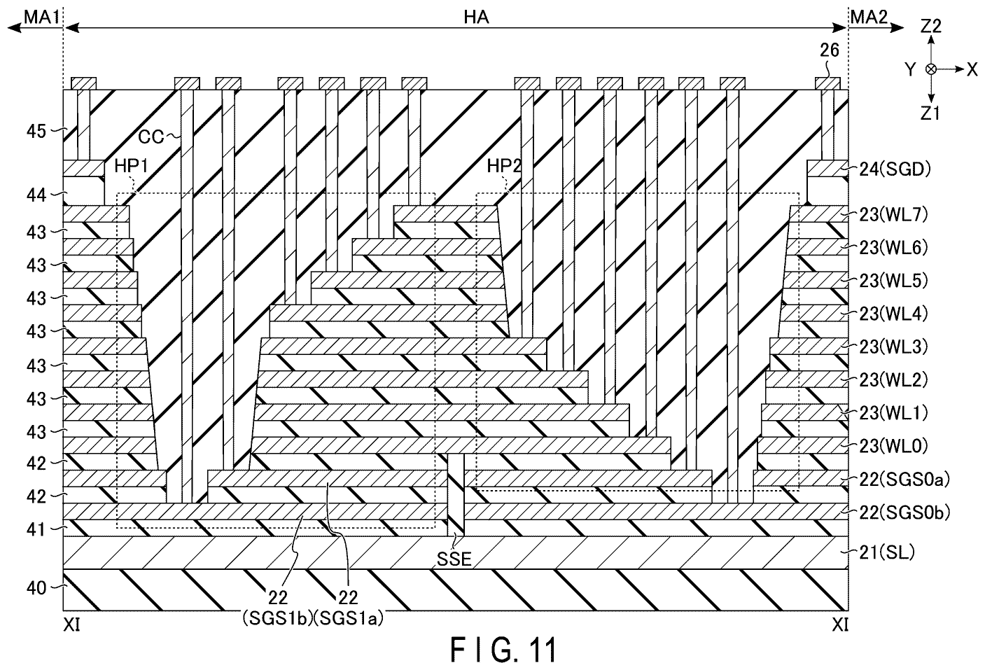

FIG. 11 is a cross-sectional view taken along line XI-XI in FIGS. 9 and 10 and shows a hookup area of the memory cell array provided in the semiconductor memory device according to the first embodiment. FIG. 11 shows an XZ cross-section of the hookup area HA and contacts CC of the block BLK1. As shown in FIG. 11, the memory cell array 10 further includes interconnect layers 26 in the hookup area HA.

As shown in FIG. 11, a first staircase structure ascending in the X direction from the memory area MA1 side toward the memory area MA2 side is formed in the hookup portion HP1. A second staircase structure descending in the X direction from the memory area MA1 side toward the memory area MA2 side is formed in the hookup portion HP2. The insulating layer 45 is provided so as to embed the first staircase structure and the second staircase structure.

The plurality of contacts CC extend in the Z direction. Each contact CC penetrates (passes through) the insulating layer 45 in the Z direction at the position where the contact CC is located in plan view. The upper face of each contact CC is in contact with the interconnect layer 26. The lower face of each contact CC is in contact with one of the interconnect layers 22-24 to which the contact CC corresponds.

A plurality of interconnect layers 26 are provided on the plurality of contacts CC, respectively. Each contact CC is electrically coupled to the row decoder module 16 via the corresponding interconnect layer 26.

### 1.2 Manufacturing Process of SGS Division Structure

A description will be given of an example of how an SGS division structure is manufactured in the memory cell array provided in the semiconductor memory device according to the first embodiment. Two manufacturing processes, namely a first manufacturing process and a second manufacturing process, are conceivable as the process for manufacturing the SGS division structure in the memory cell array 10 provided in the semiconductor memory device 3 according to the first embodiment. In the present embodiment, as a method of forming a plurality of interconnect layers 22, 23 and 24 corresponding to the select gate lines SGS and SGD and the word lines WL0 to WL7, a description will be given of a method in which structures corresponding to the interconnect layers 22, 23, and 24 are first formed from sacrificial members, and then the interconnect layers 22, 23 and 24 are formed by replacing the sacrificial members with conductive materials (hereinafter referred to as “replacement”).

### 1.2.1 First Manufacturing Process

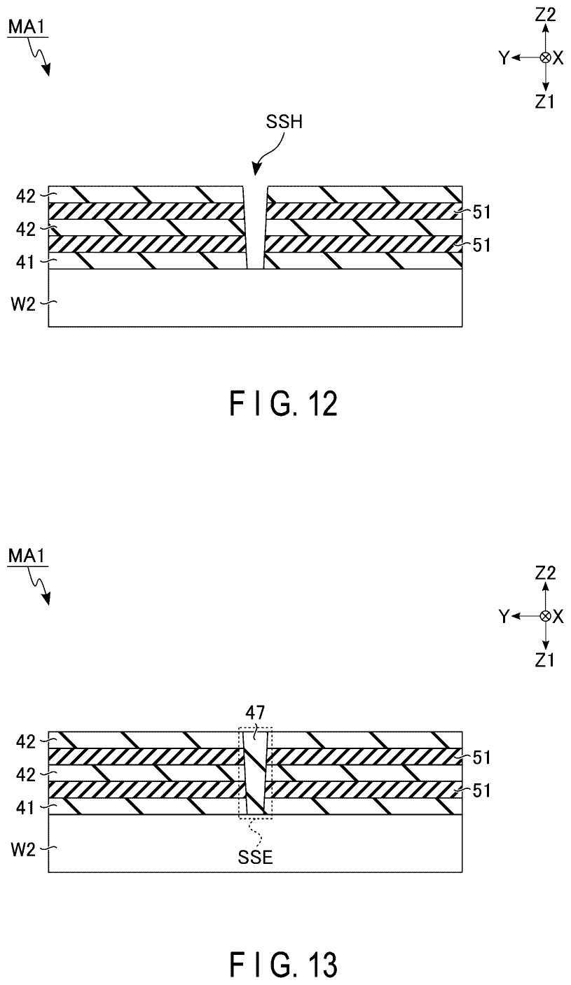

In the first manufacturing process of the SGS division structure, a member SSE is formed before the replacement of interconnect layers, and a sacrificial member corresponding to the select gate line SGS is divided. FIGS. 12 and 13 are cross-sectional views showing an example of the first manufacturing process in which the SGS division structure is fabricated in the memory cell array provided in the semiconductor memory device according to the first embodiment. It should be noted that the cross sections shown in FIGS. 12 and 13 correspond to the cross sections of the memory area MA1, but a similar manufacturing process is used for manufacturing an SGS division structure in the memory area MA2 and the hookup area HA.

First, an insulating layer 41 is stacked on the semiconductor substrate W2, and sacrificial members 51 and insulating layers 42 are alternately stacked above the insulating layer 41. The sacrificial members 51 are provided at positions corresponding to interconnect layers 22. The sacrificial members 51 contain, for example, silicon nitride.

Thereafter, as shown in FIG. 12, a slit SSH corresponding to a member SSE is provided. Specifically, a mask having an opening at a position corresponding to the member SSE is first formed by photolithography or the like. Then, the insulating layers 41 and 42 and the sacrificial members 51 are removed by anisotropic etching using the mask. Part of the semiconductor substrate W2 is exposed at the bottom of the slit SSH. The bottom of the slit SSH may be located within the insulating layer 41. In that case, part of the insulating layer 41 is exposed at the bottom of the slit SSH. The slit SSH has a tapered shape tapered in the Z1 direction.

Next, as shown in FIG. 13, the slit SSH is filled with an insulator 47 to form the member SSE. The insulator 47 contains, for example, silicon oxide. For example, the surfaces of the insulating layers 42 and the member SSE are made flat by CMP (Chemical Mechanical Polishing).

Thereafter, sacrificial members corresponding to interconnect layers 23 and 24 and insulating layers are stacked above the insulating layer 42 and the member SSE, thereby forming a staircase structure.

The member SSE fabricated by the first manufacturing process has a tapered shape tapered in the Z1 direction.

### 1.2.2 Second Manufacturing Process

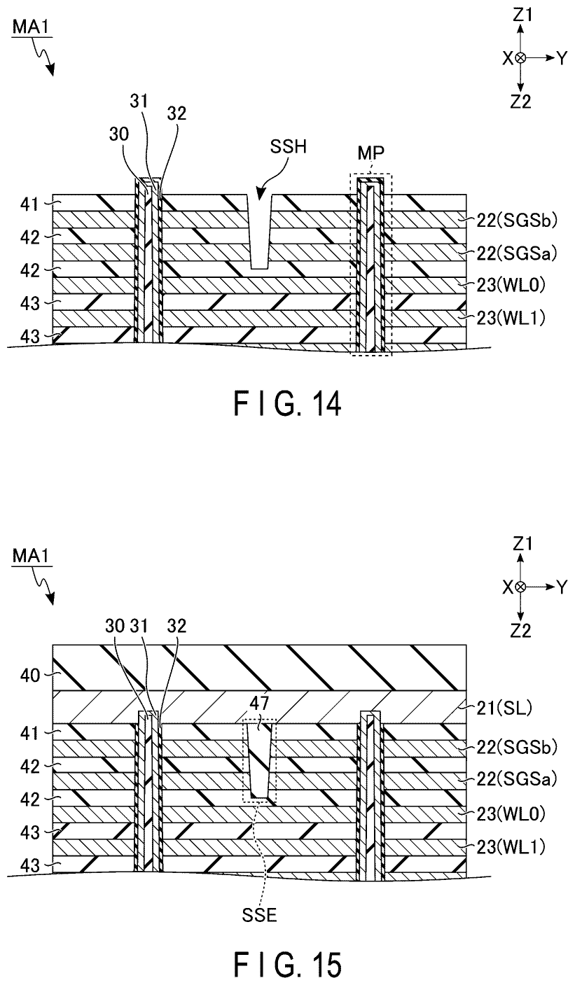

In the second manufacturing process of the SGS division structure, a member SSE is formed after the replacement of interconnect layers, and the select gate line SGS is divided. FIGS. 14 and 15 are cross-sectional views showing an example of the second manufacturing process in which an SGS division structure is fabricated in the memory cell array provided in the semiconductor memory device according to the first embodiment. It should be noted that the cross sections shown in FIGS. 14 and 15 correspond to the cross sections of the memory area MA1, but a similar manufacturing process is used for manufacturing an SGS division structure in the memory area MA2 and the hookup area HA.

First, a memory cell array 10 which does not include an interconnect layer 21 and in which select gate lines SGSa and SGSb are not divided is formed on a semiconductor substrate W2. Specifically, an insulating layer 41 is formed on the semiconductor substrate W2. Then, sacrificial members corresponding to interconnect layers 22, 23, and 24 and insulating layers are stacked above the insulating layer 41, staircase structures are formed, and memory pillars MP and members SLT are formed. The lower end (shown at the upper portion of the drawing sheet) of each of the memory pillars MP is located in the semiconductor substrate W2. In this case, a semiconductor film 31 is not exposed at the lower end of each of the memory pillars MP, and is covered with a stacked film 32. The lower end (shown at the upper portion of the drawing sheet) of each of the members SLT is in contact with the semiconductor substrate W2. Then, as shown in FIG. 4, the control circuits provided in the control circuit layer 100 and the memory cell arrays 10 provided in the memory layer 200 are electrically coupled to each other via the bonding pads BP1 and BP2.

Then, the semiconductor substrate W2 is removed. Thereafter, as shown in FIG. 14, a slit SSH corresponding to the member SSE is provided. Specifically, a mask having an opening at a position corresponding to the member SSE is first formed by photolithography or the like. Then, part of the insulating layer 41, the interconnect layer 22 and the insulating layer 42 are removed by anisotropic etching using the mask. At the bottom of the slit SSH, part of the uppermost insulating layer 42 (shown at the lower portion of the drawing sheet) or part of the lowermost interconnect layer 23 (shown at the upper portion of the drawing sheet) is exposed. The slit SSH has a tapered shape tapered in the Z2 direction.

Next, the slit SSH is filled with an insulator 47 to form the member SSE. The insulator 47 contains, for example, silicon oxide.

Thereafter, part of the stacked film 32 of the memory pillar MP is removed to expose part of the semiconductor film 31. Next, an interconnect layer 21 is formed on the Z1-direction faces of the insulating layer 41 and the member SSE. Specifically, for example, a semiconductor layer containing polysilicon is formed on the Z1-direction faces of the insulating layer 41 and the member SSE. Thereafter, a laser annealing process is performed on the semiconductor layer to dope the semiconductor layer with impurities (for example, phosphorus), thereby forming a conductive interconnect layer 21. At this time, the interconnect layer 21 and the semiconductor film 31 of the memory pillar MP are electrically coupled to each other. In addition, an insulating layer 40 is formed on the Z1-direction face of the interconnect layer 21.

The member SSE fabricated by the second manufacturing process has a tapered shape tapered in the Z2 direction.

### 1.3 Advantages of First Embodiment

According to the first embodiment, the driving speed of the semiconductor memory device can be improved. This advantage will be described in detail below.

In the semiconductor memory device 3 according to the first embodiment, the select gate lines SGSa and SGSb are divided as two portions in one block BLK. Therefore, when the memory cell array 10 operates, the select gate lines SGSa and SGSb corresponding to the memory pillar MP in which the selected memory cell transistor MT is formed can be selectively driven. Specifically, for example, when data is read from or written to the memory pillar MP provided in the string unit SU0, the select gate lines SGS0a and SGS0b are driven, and the select gate lines SGS1a and SGS1b are not driven. Thus, in comparison with a structure in which the select gate lines are not divided, the cross-sectional area of the select gate lines SGS0a and SGS1a in the XY plane is approximately half, and the electric capacitance of each of them is also reduced. Therefore, the time required to charge each of the select gate lines SGS0a and SGS1a can be short, and the driving speed is improved. Similarly, the cross-sectional area of the select gate lines SGS0b and SGS1b in the XY plane is approximately half, and the electric capacitance of each them is also reduced. Therefore, the time required to charge each of the select gate lines SGS0b and SGS1b can be short, and the driving speed is improved.

In the semiconductor memory device 3 according to the first embodiment, each of the select gate lines SGS0a, SGS1a, SGS0b, and SGS1b is designed such that a portion provided in the memory area MA1 and a portion provided in the memory area MA2 are coupled to each other via a bridge portion BRG formed in the hookup area HA. In other words, each of the select gate lines SGS0a, SGS1a, SGS0b, and SGS1b is not divided as a plurality of portions, and no coupling is made via an upper interconnect or the like. Therefore, in comparison with a structure in which each select gate line is divided in the X direction as a plurality of portions and coupling is made using an upper interconnect, the electrical capacitance of each of the select gate lines SGS0a, SGS1a, SGS0b and SGS1b can be reduced. In other words, the time required to charge each of the select gate lines SGS0a, SGS1a, SGS0b, and SGS1b can be short, and the driving speed is improved.

Additionally, in the semiconductor memory device 3 according to the first embodiment, the member SSE is not provided at a position overlapping the member SLT in the Z direction. For this reason, when a slit corresponding to the member SLT is formed, deep etching caused by differences in etching selectivity can be prevented in areas where the member SSE is present. Therefore, short circuits caused by deep etching in areas where the member SSE is present can be suppressed between the select gate lines SGS0a and SGS1a and between the select gate lines SGS0b and SGS1b, thereby improving the yield of the semiconductor memory device 3.

### 1.4 Modification

The semiconductor memory device 3 according to the first embodiment described above can be modified in various manners. The following describes the differences in a first modification of the first embodiment.

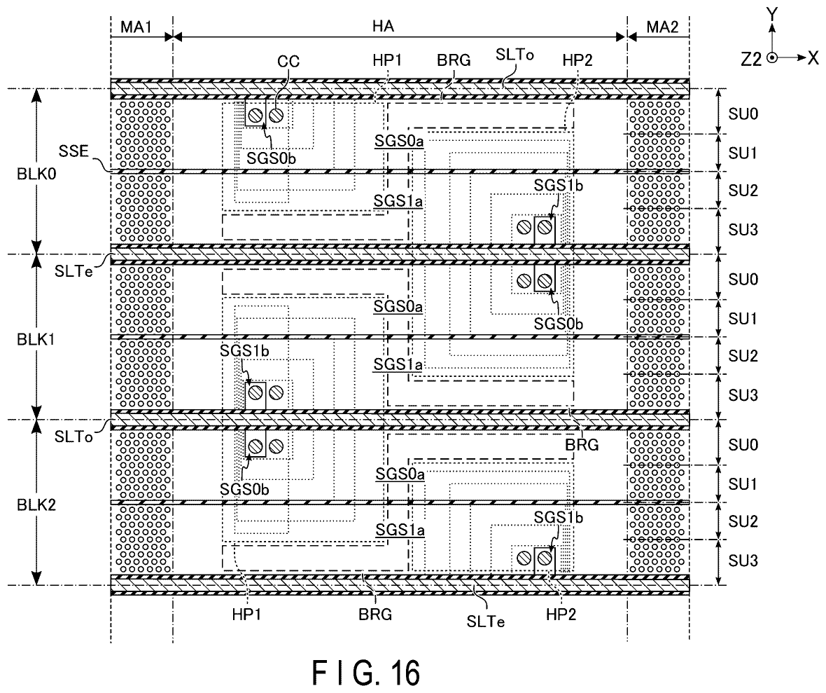

FIG. 16 is a plan view showing an example of a planar layout of a select gate line SGSa in a hookup area of the memory cell array provided in the semiconductor memory device according to the first modification of the first embodiment. FIG. 16 shows the hookup area HA and portions of the neighboring memory areas MA1 and MA2. The area shown in FIG. 16 corresponds to blocks BLK0 to BLK2. It should be noted that some insulating layers are omitted in FIG. 16 for the sake of simplicity. Furthermore, in FIG. 16, the positions of the interconnect layers (word lines WL0 to WL7) located above the select gate line SGSa in a plan view are indicated by dotted lines.

In the memory cell array 10 provided in the semiconductor memory device 3 according to the first modification of the first embodiment, the member SSE may be provided in the hookup portion HP1 or HP2. The member SSE is formed, for example, in a plate shape spreading along the XZ plane. The member SSE is provided, for example, below the terrace portion of the interconnect layer provided above the select gate line SGSa. In a case where the member SSE is provided in the hookup portion HP1, the member SSE is positioned, in a plan view, on the side of the member SLTe adjacent to the block BLK where the member SSE is installed, rather than on the terrace portions of the select gate lines SGSa and SGSb. In a case where the member SSE is provided in the hookup portion HP2, the member SSE is positioned, in a plan view, on the side of the member SLTo adjacent to the block BLK where the member SSE is installed, rather than on the terrace portions of the select gate lines SGSa and SGSb. Additionally, in a case where there are three or more interconnect layers 22 corresponding to the select gate line SGS, the member SSE is provided in such a way that it does not divide each interconnect layer 22 into the memory area MA1 portion and the memory area MA2 portion.

### 2. Second Embodiment

Next, a description will be given of a semiconductor memory device according to a second embodiment. The semiconductor memory device 3 according to the second embodiment differs from the semiconductor memory device 3 according to the first embodiment in that it further includes a member SLTp. In the description below, configurations and manufacturing processes similar to those of the first embodiment will not be mentioned, and the configurations different from those of the first embodiment will be mainly mentioned.

### 2.1 Structure of Memory Cell Array

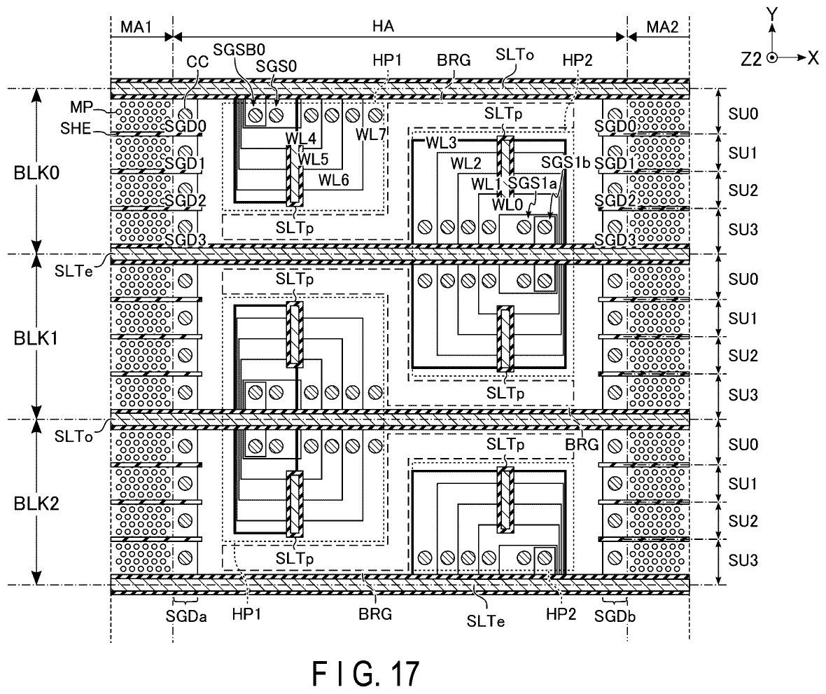

FIG. 17 is a plan view showing an example of a planar layout in the hookup area of the memory cell array provided in the semiconductor memory device according to the second embodiment. As shown in FIG. 17, the memory cell array 10 provided in the semiconductor memory device 3 according to the second embodiment further includes a plurality of members SLTp. It should be noted that, in the second embodiment, the portion of the member SSE within the hookup area HA is positioned in the bridge portion BRG such that it bypasses the hookup portions HP1 and HP2 and does not overlap the member SLT in the Z direction in a plan view.

Each member SLTp has, for example, a plate-like shape extending in the YZ plane. Each member SLTp has, for example, a structure in which an insulator and a plate-like contact are embedded. Each member SLTp penetrates (passes through) the select gate lines SGSa and SGSb, the word lines WL0 to WL7, and the insulator layers 41, 42, 43, 44 and 45 in the Z direction. Each member SLTp is in contact with the interconnect layer 21 at the lower end, for example.

As shown in FIG. 17, each member SLTp is provided in the hookup portion HP1 or HP2 such that it does not divide the select gate lines SGSa and SGSb and the word lines WL0 to WL7 in the X direction. Therefore, each member SLTp is provided in such a manner that it is not in contact with the member SSE. Each member SLTp may be positioned at any position within the hookup area HA, provided that it is included in the hookup portion HP1 or HP2 and does not overlap, in the Z direction, a portion coupled to the corresponding contact CC in the terrace portion of the stacked interconnects. Each member SLTp is provided so as to cross the first staircase structure or the second staircase structure in the Y direction, for example.

The shape of the member SLTp is not important as long as it is large enough to accommodate a conductive material (e.g., tungsten) poured during the replacement step of the manufacturing process. For example, the member SLTp may have a pillar shape.

### 2.2 Advantages of the Second Embodiment

According to the second embodiment, the driving speed of the semiconductor memory device can be improved, as in the first embodiment.

Additionally, the second embodiment allows for an improvement in the yield of the semiconductor memory device. This advantage will be described in detail below.

When the semiconductor memory device 3 according to the second embodiment is manufactured, the replacement of the interconnect layers 22 corresponding to the select gate lines SGSa and SGSb is performed through slits formed in the portions corresponding to the member SLT and the member SLTp. At this time, if the SGS division structure is formed using the same steps as the first manufacturing process in the first embodiment, the presence of a slit corresponding to the member SLTp shortens the distance between the farthest end of the interconnect layer 22 and the nearest slit. As a result, during the replacement of the interconnect layers 22, the conductive material (e.g., tungsten) reliably flows to the farthest end of interconnect layer 22, thereby preventing the generation of voids. Consequently, the yield of the semiconductor memory device 3 can be improved.

### 2.3 Modification

The semiconductor memory device 3 according to the second embodiment described above can be modified in various manners. The following describes the points in which a first modification of the second embodiment differs from the second embodiment.

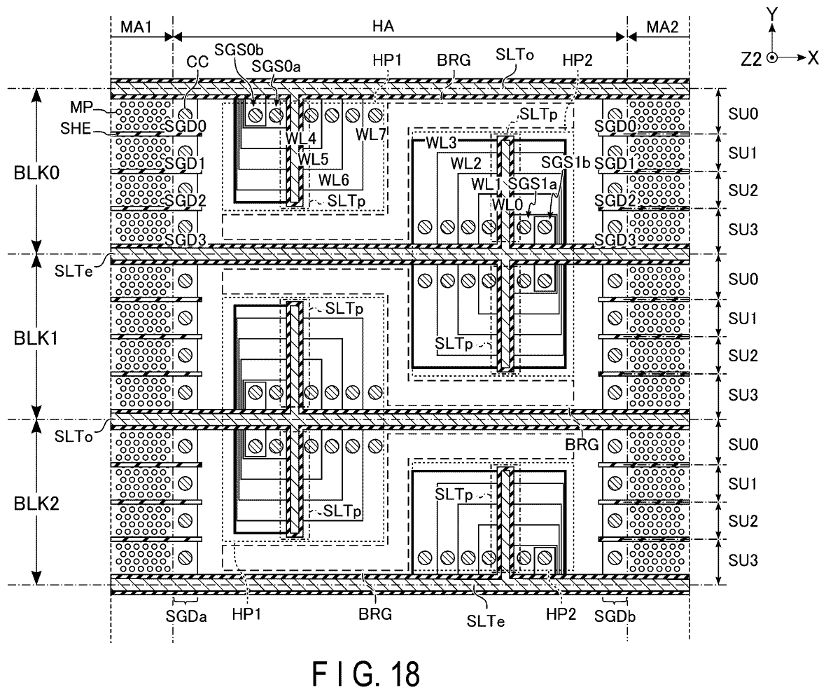

FIG. 18 is a plan view showing an example of a planar layout in the hookup area of the memory cell array provided in the semiconductor memory device according to the first modification of the second embodiment. As shown in FIG. 18, in the memory cell array 10 provided in the semiconductor memory device 3 according to the first modification of the second embodiment, the member SLTp is in contact with the member SLT in the Y direction, and these members are formed as a single member. In other words, the member SLTp can be regarded as a portion of the member SLT protruding into the hookup portion HP1 or HP2. Likewise, the member SLTp provided in the hookup portion HP1 is in contact with the member SLTo, and these members can be formed as a single member. The member SLTp provided in the hookup portion HP2 is in contact with the member SLTe, and these members are formed as a single member.

According to the first modification of the second embodiment, the driving speed of the semiconductor memory device can be improved, as in the second embodiment. Furthermore, the yield of the semiconductor memory device can be improved, as in the second embodiment.

### 3. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a first interconnect layer provided on a first area;
a second interconnect layer arranged apart from the first interconnect layer in a first direction and provided across the first area and a second area that are arranged along a second direction intersecting the first direction;
a plurality of third interconnect layers provided on a side of the second interconnect layer that is opposite to the first interconnect layer, and spaced apart from each other in the first direction;
a first insulating member and a second insulating member which are arranged in a third direction intersecting the first direction and the second direction, and each of which extends in the second direction and divides the second interconnect layer and the plurality of third interconnect layers in the third direction;
a third insulating member provided between the first insulating member and the second insulating member and between the first interconnect layer and the plurality of third interconnect layers, and dividing the second interconnect layer into a first portion and a second portion in the third direction;
a first memory pillar extending in the first direction between the first insulating member and the third insulating member in the second area, being in contact with the first interconnect layer, intersecting the first portion of the second interconnect layer, and including portions that intersect the plurality of third interconnect layers and that function as a plurality of first memory cells;
a second memory pillar extending in the first direction between the second insulating member and the third insulating member in the second area, being in contact with the first interconnect layer, intersecting the second portion of the second interconnect layer, and including portions that intersect the plurality of third interconnect layers and that function as a plurality of second memory cells; and
a first contact and a second contact that extend in the first direction in the first area,
wherein the second interconnect layer includes:
a first terrace portion that is arranged in the first portion within the first area and that is in contact with the first insulating member and does not overlap the plurality of third interconnect layers as viewed in the first direction; and
a second terrace portion that is arranged in the second portion within the first area and that is in contact with the second insulating member and does not overlap the plurality of third interconnect layers as viewed in the first direction,
the first contact is electrically coupled to the first terrace portion of the second interconnect layer, and
the second contact is electrically coupled to the second terrace portion of the second interconnect layer.

2. The semiconductor memory device according to claim 1, wherein
in the first area, each of the plurality of third interconnect layers includes:
a first bridge portion that is in contact with the second insulating member and extends in the second direction between the first terrace portion of the second interconnect layer and the second insulating member,
a second bridge portion that is in contact with the first insulating member and extends in the second direction between the second terrace portion of the second interconnect layer and the first insulating member, and
a third bridge portion that extends in the third direction between the first insulating member and the second insulating member and is in contact with the first bridge portion and the second bridge portion.

3. The semiconductor memory device according to claim 2, further comprising:
a third contact and a fourth contact that extend in the first direction within the first area,
wherein the plurality of third interconnect layers include a fourth interconnect layer and a fifth interconnect layer,
the fourth interconnect layer includes a third terrace portion that is in contact with the first insulating member in the first area and does not overlap upper layers of the plurality of third interconnect layers as viewed in the first direction,
the fifth interconnect layer includes a fourth terrace portion that is in contact with the second insulating member in the first area and does not overlap upper layers of the plurality of third interconnect layers as viewed in the first direction,
the third contact is electrically coupled to the third terrace portion of the fourth interconnect layer, and
the fourth contact is electrically coupled to the fourth terrace portion of the fifth interconnect layer.

4. The semiconductor memory device according to claim 3, wherein the third insulating member is provided in the first area at a position overlapping each of the first bridge portion, the second bridge portion and the third bridge portion of the plurality of third interconnect layers in the first direction.

5. The semiconductor memory device according to claim 4, wherein the third insulating member includes:
a third portion extending in the second direction and arranged in the first area at a position overlapping the first bridge portion of the plurality of third interconnect layers in the first direction;
a fourth portion extending in the second direction and arranged in the first area at a position overlapping the second bridge portion of the plurality of third interconnect layers in the first direction; and
a fifth portion that is arranged in the first area, that extends in the third direction at a position overlapping the third bridge portion of the plurality of third interconnect layers in the first direction, and that is in contact with the third portion and the fourth portion.

6. The semiconductor memory device according to claim 1, wherein an electric capacitance of the first portion of the second interconnect layer and an electric capacitance of the second portion of the second interconnect layer are substantially equal to each other.

7. The semiconductor memory device according to claim 3, wherein the third insulating member is provided at a position overlapping the third terrace portion of the fourth interconnect layer or the fourth terrace portion of the fifth interconnect layer in the first direction.

8. The semiconductor memory device according to claim 1, further comprising:
a control circuit that applies voltages independently to the first portion and the second portion of the second interconnect layer.

9. The semiconductor memory device according to claim 1, further comprising:
a sixth interconnect layer arranged on a side of the plurality of third interconnect layers that is opposite to the second interconnect layer, and spaced apart from each other in the first direction; and
a fourth insulating member that divides the sixth interconnect layer in the third direction between the first insulating member and the second insulating member,
wherein the first terrace portion and the second terrace portion of the second interconnect layer do not overlap the sixth interconnect layer as viewed in the first direction,
the first memory pillar and the second memory pillar intersect the sixth interconnect layer, and
the third insulating member and the fourth insulating member are arranged in the second area at positions overlapping each other in the first direction.

10. The semiconductor memory device according to claim 1, wherein the third insulating member is in contact, in the first direction, with an interconnect layer that is among the plurality of third interconnect layers and that is provided closest to the first interconnect layer, and the third insulating member has a tapered shape that narrows from a side of the plurality of third interconnect layers toward a side of the first interconnect layer.

11. The semiconductor memory device according to claim 1, wherein the third insulating member is in contact with the first interconnect layer in the first direction and has a tapered shape that narrows from a side of the first interconnect layer toward a side of the plurality of third interconnect layers.

12. The semiconductor memory device according to claim 1, further comprising:
a third memory pillar and a fourth memory pillar,
wherein the first interconnect layer, the second interconnect layer, and the plurality of third interconnect layers further include a third area that sandwiches the first area in the second direction together with the second area,
the third memory pillar extends in the first direction between the first insulating member within the third area and the third insulating member, is in contact with the first interconnect layer, intersects the first portion of the second interconnect layer, and includes portions that intersect the plurality of third interconnect layers and that function as a plurality of third memory cells, and
the fourth memory pillar extends in the first direction between the second insulating member and the third insulating member in the third area, is in contact with the first interconnect layer, intersects the second portion of the second interconnect layer, and includes portions that intersect the plurality of third interconnect layers and that function as a plurality of fourth memory cells.

13. The semiconductor memory device according to claim 12, wherein
in the first portion of the second interconnect layer, a portion provided in the second area and a portion provided in the third area are in contact with each other, with a portion provided in the first area being interposed, and
in the second portion of the second interconnect layer, a portion provided in the second area and a portion provided in the third area are in contact with each other, with a portion provided in the first area being interposed.

14. The semiconductor memory device according to claim 12, further comprising:
a sixth interconnect layer provided on a side of the plurality of third interconnect layers that is opposite to the second interconnect layer, and spaced apart from each other in the first direction; and
a fourth insulating member that divides the sixth interconnect layer in the third direction between the first insulating member and the second insulating member,
wherein the first terrace portion and the second terrace portion of the second interconnect layer do not overlap the sixth interconnect layer as viewed in the first direction,
the third memory pillar and the fourth memory pillar intersect the sixth interconnect layer, and
the third insulating member and the fourth insulating member are arranged in the third area at positions that overlap each other in the first direction.

15. The semiconductor memory device according to claim 1, further comprising:
a fifth insulating member that is not in contact with the third insulating member between the first insulating member and the third insulating member in the first area, and that passes through the first portion of the second interconnect layer and the plurality of third interconnect layers in the first direction; and
a sixth insulating member that is not in contact with the third insulating member between the second insulating member and the third insulating member in the first area, and that passes through the second portion of the second interconnect layer and the plurality of third interconnect layers in the first direction.

16. The semiconductor memory device according to claim 15, wherein
the fifth insulating member is in contact with the first insulating member in the third direction, and
the sixth insulating member is in contact with the second insulating member in the third direction.

17. The semiconductor memory device according to claim 15, wherein the fifth insulating member and the sixth insulating member are provided at positions that do not overlap the first contact and the second contact in the first direction.

18. The semiconductor memory device according to claim 1, further comprising:
a seventh interconnect layer sandwiched between the first interconnect layer and the second interconnect layer in the first direction and spaced apart from each other in the first direction; and
a fifth contact and a sixth contact that extend in the first direction within the first area,
wherein the third insulating member divides the seventh interconnect layer into a sixth portion and a seventh portion in the third direction,
the seventh interconnect layer includes a fifth terrace portion that is in contact with the first insulating member in the sixth portion in the first area and that does not overlap any of the second interconnect layer and the plurality of third interconnect layers as viewed in the first direction, and a sixth terrace portion that is in contact with the second insulating member in the seventh portion in the first area and that does not overlap any of the second interconnect layer and the plurality of third interconnect layers as viewed in the first direction,
the first memory pillar intersects the sixth portion of the seventh interconnect layer,
the second memory pillar intersects the seventh portion of the seventh interconnect layer,
the fifth contact is electrically coupled to the fifth terrace portion of the seventh interconnect layer, and
the sixth contact is electrically coupled to the sixth terrace portion of the seventh interconnect layer.

19. The semiconductor memory device according to claim 18, further comprising:
a control circuit,
wherein the control circuit is configured to:
apply voltages independently to the first and second portions of the second interconnect layer, and
apply voltages independently to the sixth and seventh portions of the seventh interconnect layers.

20. The semiconductor memory device according to claim 19, wherein
the control circuit is further configured to:
apply voltages of approximately equal magnitudes to the first portion of the second interconnect layer and the sixth portion of the seventh interconnect layer, and
apply voltages of approximately equal magnitudes to the second portion of the second interconnect layer and the seventh portion of the seventh interconnect layer.
